(19) United States
(12) Patent Application Publication
(10) Pub. No.: US 2010/0045281 A1
(43) Pub. Date: Feb. 25, 2010

(54) ARRANGEMENT AND METHOD FOR DETECTING AND/OR LOCATING A MAGNETIC MATERIAL IN A REGION OF ACTION, USE OF AN ARRANGEMENT IN THE EXAMINATION OF BUILDINGS

(75) Inventors: Bernhard Gleich, Eindhoven (NL); Jurgen Weizenecker, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/519,781

(22) PCT Filed: Dec. 17, 2007
(86) PCT No.: PCT/IB07/55178

§ 371 Date: Nov. 11, 2009

(30) Foreign Application Priority Data
Dec. 20, 2006 (EP) 06126572.4

(51) Int. Cl. G01R 33/12

(52) U.S. Cl. 324/239

(57) ABSTRACT

An arrangement and a method for detecting and/or locating magnetic material, and the use of an arrangement in the examination of buildings is disclosed, which arrangement comprises: selection means for generating a magnetic selection field having a pattern in space of its magnetic field strength such that a first sub-zone having a low magnetic field strength and a second sub-zone having a higher magnetic field strength are formed in the region of action, drive means for changing the position in space of the two sub-zones in the region of action by means of a magnetic drive field so that the magnetization of the magnetic material changes locally, receiving means for acquiring detection signals, which detection signals depend on the magnetization in the region of action, which magnetization is influenced by the change in the position in space of the first and second sub-zone, wherein the magnetic selection field comprises at least a time-variable field component varying at a frequency of at least about 100 Hz.

The present invention relates to an arrangement for detecting and/or locating a magnetic material in a region of action. Furthermore, the invention relates to a method for detecting and/or locating a magnetic material in a region of action and to the use of an inventive arrangement in the examination of buildings.

An arrangement and a method of this kind is known from German patent application DE 101 51 778 A1. In the case of the method described in that publication, first of all a magnetic field having a spatial distribution of the magnetic field strength is generated such that a first sub-zone having a relatively low magnetic field strength and a second sub-zone having a relatively high magnetic field strength are formed in the examination zone. The position in space of the sub-zones in the examination zone is then shifted, so that the magnetization of the particles in the examination zone changes locally. Signals are recorded which are dependent on the magnetization in the examination zone, which magnetization has been influenced by the shift in the position in space of the sub-zones, and information concerning the spatial distribution of the magnetic particles in the examination zone is extracted from these signals, so that an image of the examination zone can be formed. Such an arrangement and such a method have the advantage that it can be used to examine arbitrary examination objects—e.g. human bodies or buildings—in a non-destructive manner and without causing any damage and with a high special resolution, both close to the surface and remote from the surface of the examination object.

From the International Patent Application WO 2004/091721 A1, an arrangement for influencing magnetic particles is known, where the arrangement is provided such that an improved accessibility of the region of action is possible.

Known arrangements of this type have shown the disadvantage that e.g. solid steel rods—e.g. as used in the construction of buildings like bridges or the like—can not be located because the demagnetization factor of such steel rods prevents the saturation of such material in a static or quasi-static selection field according to known arrangements, i.e. at absolute field strength of the selection field largely inferior to about 1 T. The application of magnetic fields of this absolute strength would make such an arrangement very bulky and expensive.

It is therefore an object of the present invention to provide an arrangement and a method of the kind mentioned initially, in which it is possible to detect and/or to locate metallic soft magnetic material including e.g. iron rods of comparably large diameter.

The above object is achieved by an arrangement for detecting and/or locating a magnetic material in a region of action, wherein the arrangement comprises
selection means for generating a magnetic selection field having a pattern in space of its magnetic field strength such that a first sub-zone having a low magnetic field strength and a second sub-zone having a higher magnetic field strength are formed in the region of action,
drive means for changing the position in space of the two sub-zones in the region of action by means of a magnetic drive field so that the magnetization of the magnetic material changes locally,
receiving means for acquiring detection signals, which detection signals depend on the magnetization in the region of action, which magnetization is influenced by the change in the position in space of the first and second sub-zone,
wherein the magnetic selection field comprises at least a time-variable field component varying at a frequency of at least about 100 Hz.

The inventive arrangement according to the present invention has the advantage that it is possible to examine a magnetic material, e.g. of the ferromagnetic type, by using a detection method similar to the kind disclosed in DE 101 51 778 A1, i.e. by using the effect of saturating the magnetic material but without having to generate magnetic fields having a comparable strength of static magnetic fields that are able to saturate the magnetic material (in its entirety). This greatly simplifies the inventive arrangement and provides a much more cost effective solution.

According to a preferred embodiment of the present invention, the magnetic selection field furthermore comprises a time-constant field component in addition to the time-variable field component of the magnetic selection field. Thereby, it is possible to further enhance the detection of the magnetic material. According to this embodiment, very different time-constant field components are possible to add to the time-variable field component of the magnetic selection field. Such time-constant field components can comprise gradient-type field components but do not need to be gradient field components; e.g. homogeneous field components are also possible. Thereby, it is, e.g. possible to enhance the permeability in certain materials to examine or to suppress the signals due to small particles (having a classical mechanism for the generation of harmonics).

Very preferably according to the present invention, the arrangement is provided as a single-sided arrangement. Thereby, it is advantageously possible to detect and/or to locate magnetic material in objects that are to large to be moved into the region of action, e.g. motorway or railway bridges, buildings in general or the like. By means of a single sided-arrangement, it is possible to approach the building part by the inventive arrangement and to locate the magnetic material underneath the surface of the building part.

Very preferably, the selection means and the drive means and the receiving means are provided as resistive coils, especially room-temperature coils. This gives the possibility to easily and flexibly arrange and change the different frequencies used with the inventive arrangement. Especially, it is possible according to a preferred embodiment of the present invention that at least the magnetic selection field is generated by means of coils with suitable magnetically soft material as core material. This reduces the needed power in order to generate sufficiently strong magnetic fields. Suitable magnetically soft materials include magnetically soft ferrites or magnetic cores made from powder material like iron powder or sendust (which is a powder core type product similar to iron powder cores). The use of a core material in coils for the drive means is in principle also possible.

The present invention further refers to a method for detecting and/or locating a magnetic material in a region of action, wherein the method comprises the steps of
generating a magnetic selection field having a pattern in space of its magnetic field strength such that a first sub-zone having a low magnetic field strength and a second sub-zone having a higher magnetic field strength are formed in the region of action,
changing the position in space of the two sub-zones in the region of action by means of a magnetic drive field formed by drive signals so that the magnetization of the magnetic material changes locally,
acquiring detection signals, which detection signals depend on the magnetization in the region of action, which magnetization is influenced by the change in the position in space of the first and second sub-zone,
wherein the magnetic selection field comprises at least a time-variable field component varying at a frequency of at least about 100 Hz.

This has the advantage that by the use of comparably low magnetic fields it is possible to the detect magnetic material which would require a comparably high static magnetic field in order to saturate (entirely).

According to a preferred embodiment of both the method and the arrangement of the present invention, it is preferred that the time-variable field component of the magnetic selection field is varying at a frequency of at least about 10 kHz, preferably of at least 25 kHz. Thereby, the frequency of the magnetic selection field can be adapted to the magnetic material to be detected.

According to a further preferred embodiment of both the method and the arrangement of the present invention, it is preferred according to the present invention, that the frequency of the time-variable field component of the magnetic selection field and the magnetic field strength of the magnetic selection field is chosen such that the magnetic material to be detected is at least partly saturated. Thereby, it is e.g. advantageously possible to flexibly use the inventive arrangement in that either a greater part of the magnetic material is saturated (by means of a lower frequency of the selection means and by means of the higher amplitude of the magnetic selection field) or that a smaller part of the material is saturated.

According to still a further preferred embodiment of both the method and the arrangement of the present invention, the magnetic drive field is a time-variable field varying at a frequency of at least about 5 times to about 100 times the frequency of the time-variable field component of the magnetic selection field. Preferably, the frequency of the magnetic drive field corresponds to about 10 times the frequency of the time-variable field component of the magnetic selection field. Thereby, the generation of an image of the magnetic material when the first sub-zone of the region of action is moved over at least a part of the region of action is not disturbed by the time-variable component of the magnetic selection field—at least for the time intervals during the positive of negative half-wave of the time-varying component of the magnetic selection field.

Preferably, the frequency of the time-variable field component of the magnetic selection field is chosen such that the magnetic field strength of the magnetic selection field in order to saturate at least partly an outer layer of the magnetic material can be chosen inferior to 500 mT, preferably inferior to 50 mT, very preferably inferior to 5 mT. Thereby, it is possible to detect and to locate the magnetic material already with comparably low magnetic fields.

The invention further relates to the use of an inventive arrangement in the examination of buildings, the buildings comprising iron rods as magnetic material inside of an insulation material. Furthermore, the invention relates to the use of an inventive arrangement in the examination of soils, especially in the search and/or classification of magnetic material in soils. Furthermore, the invention relates to the use of an inventive arrangement in the examination of human and/or animal bodies, especially in the search and/or localization of objects of magnetic material, e.g. bullets, shell splitters or the like.

These and other characteristics, features and advantages of the present invention will become apparent from the following detailed description, taken in conjunction with the accompanying drawings, which illustrate, by way of example, the principles of the invention. The description is given for the sake of example only, without limiting the scope of the invention. The reference figures quoted below refer to the attached drawings.

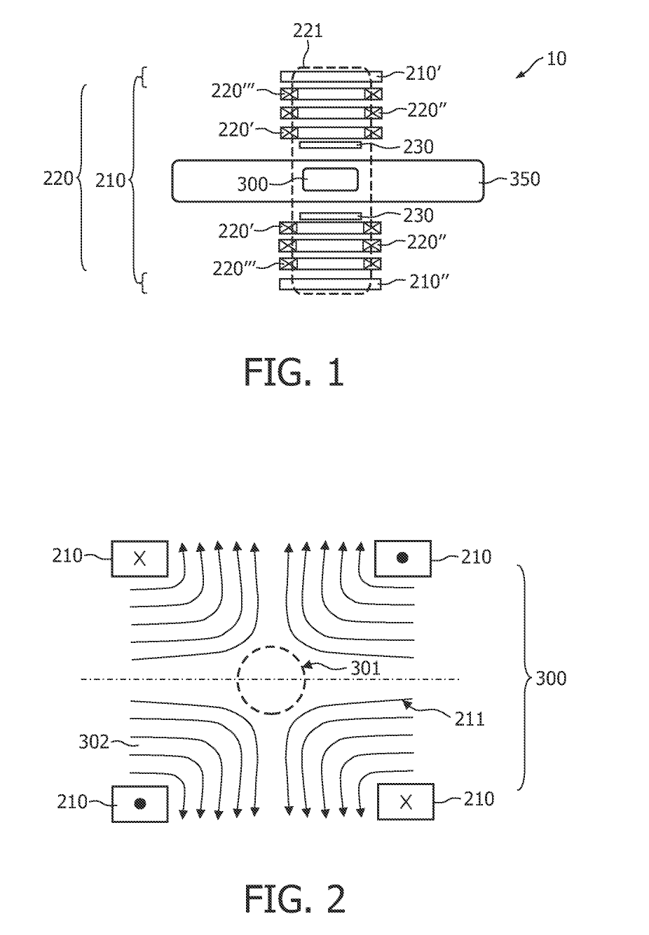

FIG. 1 illustrates an arrangement according to the present invention for carrying out the method according to the present invention.

FIG. 2 illustrates an enlarged view of a magnetic material present in the region of action.

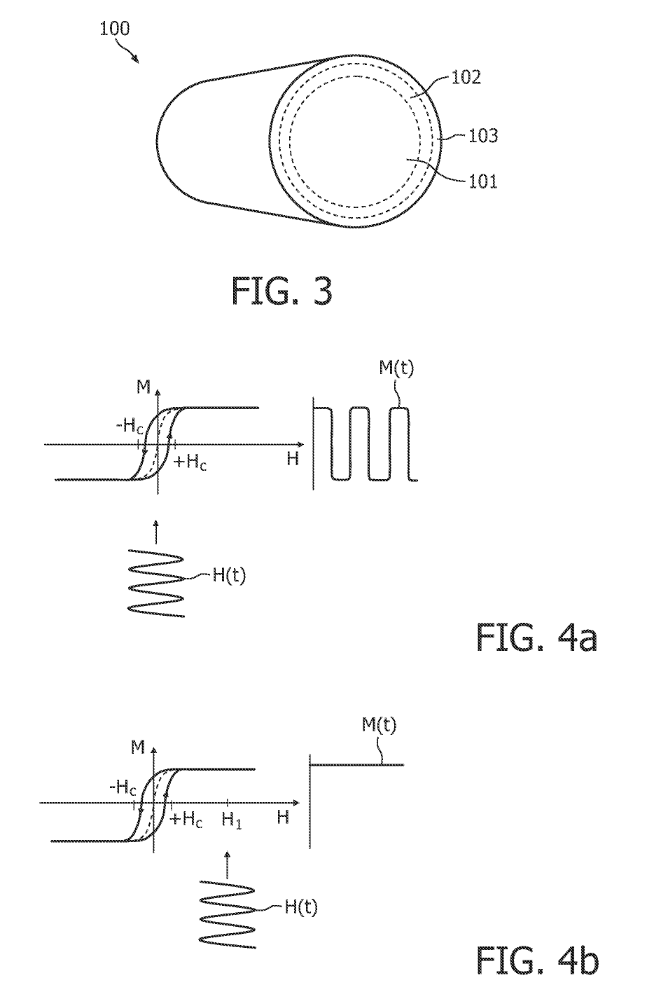

FIG. 3 illustrates an example of the field pattern produced by an arrangement according to the present invention during the positive or negative half wave of the time-varying component of the magnetic selection field.

FIG. 4a and 4b illustrate the magnetization characteristics of such a magnetic material.

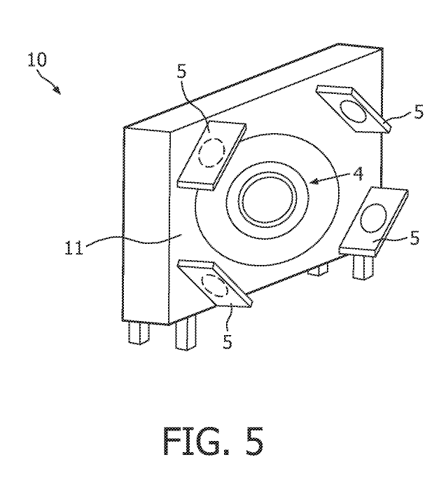

FIG. 5 illustrates schematically a single-sided arrangement 10 according to the present invention.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes.

Where an indefinite or definite article is used when referring to a singular noun, e.g. “a”, “an”, “the”, this includes a plural of that noun unless something else is specifically stated.

Furthermore, the terms first, second, third and the like in the description and in the claims are used for distinguishing between similar elements and not necessarily for describing a sequential or chronological order. It is to be understood that the terms so used are interchangeable under appropriate circumstances and that the embodiments of the invention described herein are capable of operation in other sequences than described of illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the present description and claims, should not be interpreted as being restricted to the means listed thereafter; it does not exclude other elements or steps. Thus, the scope of the expression “a device comprising means A and B” should not be limited to devices consisting only of components A and B. It means that with respect to the present invention, the only relevant components of the device are A and B.

In FIG. 1, an arbitrary object to be examined by means of an arrangement 10 according to the present invention is shown. The reference numeral 350 in FIG. 1 denotes an object, e.g. concrete part comprising a steel reinforcement. By the positioning of the object 350 inside the arrangement 10 or into a hole of the arrangement 10, the magnetic material 100 (not shown in FIG. 1) is positioned inside a region of action 300 of the inventive arrangement 10.

As an example of an embodiment of the present invention, an arrangement 10 is shown in FIG. 2 comprising a plurality of coils forming a selection means 210 whose range defines the region of action 300 which is also called the region of examination 300. For example, the selection means 210 is arranged above and below the object 350. For example, the selection means 210 comprise a first pair of coils 210′, 210″, each comprising two identically constructed windings 210′ and 210″ which are arranged coaxially above and below the object 350 and which are traversed by equal currents, especially in opposed directions. The first coil pair 210′, 210″ together are called selection means 210 in the following. Preferably, alternating currents are used in this case. The selection means 210 generate a magnetic selection field 211 (during the positive or negative half wave of the alternating currents) which is in general a gradient magnetic field which is represented in FIG. 2 by the field lines. It has a substantially constant gradient in the direction of the (e.g. vertical) axis of the coil pair of the selection means 210 and reaches the value zero in a point on this axis. Starting from this field-free point (not individually shown in FIG. 2), the field strength of the magnetic selection field 211 increases in all three spatial directions as the distance increases from the field-free point. In a first sub-zone 301 or region 301 which is denoted by a dashed line around the field-free point the field strength is so small that the magnetization of the magnetic material 100 present in that first sub-zone 301 is not partially saturated, whereas the magnetization of the magnetic material 100 present in a second sub-zone 302 (outside the region 301) is in a state of partial saturation. The field-free point or first sub-zone 301 of the region of action 300 is preferably a spatially coherent area; it may also be a punctiform area or else a line or a flat area. In the second sub-zone 302 (i.e. in the residual part of the region of action 300 outside of the first sub-zone 301) the magnetic field strength is sufficiently strong to keep some fraction of the magnetic material 100 in a state of saturation. By changing the position of the two sub-zones 301, 302 within the region of action 300, the (overall) magnetization in the region of action 300 changes. By measuring the magnetization in the region of action 300 or a physical parameter influenced by the magnetization, information about the spatial distribution of the magnetic material in the region of action can be obtained.

When a further magnetic field—in the following called a magnetic drive field 221 is superposed on the magnetic selection field 210 (or gradient magnetic field 210) in the region of action 300, the first sub-zone 301 is shifted relative to the second sub-zone 302 in the direction of this magnetic drive field 221; the extent of this shift increases as the strength of the magnetic drive field 221 increases. When the superposed magnetic drive field 221 is variable in time, the position of the first sub-zone 301 varies accordingly in time and in space. It is advantageous to receive or to detect signals from the magnetic material 100 located in the first sub-zone 301 in another frequency band (shifted to higher frequencies) than the frequency band of the magnetic drive field 221 variations. This is possible because frequency components of higher harmonics of the magnetic drive field 221 frequency occur due to a change in magnetization of the magnetic material 100 in the region of action 300 as a result of the non-linearity of the magnetization characteristics, i.e. the due to saturation effects.

The arrangement 10 according to the present invention further comprise receiving means 230 that are only schematically shown in FIG. 1. The receiving means 230 usually comprise coils that are able to detect the signals induced by the magnetization pattern of the magnetic material 100 in the region of action 300. Coils of this kind, however, are known from the field of magnetic resonance apparatus in which e.g. a radio frequency (RF) coil pair is situated around the region of action 300 in order to have a signal to noise ratio as high as possible. Therefore, the construction of such coils need not be further elaborated herein.

Such an arrangement and such a method of detecting a magnetic material (in the form of magnetic particles) are known from DE 101 51 778 which is hereby incorporated in its entirety.

According to the present invention, the magnetic material 100 is e.g. a ferromagnetic material such that it necessitates a comparably high static magnetic field if saturation effects are to be seen. Such a high static magnetic selection field would bring the need for a very large and expensive arrangement 10 if the arrangement known form DE 101 51 778 was to be used. According to the present invention, the selection field is not static or quasi static but time-variable or comprises at least a time-variable component. Thereby, it is possible to confine the magnetic flux induced by the magnetic selection field in the outer (periphery) parts of the magnetic material 100. This is due to the skin effect that becomes significant if a time-varying magnetic field of sufficient frequency is interacting with conducting material. By applying the time-variable magnetic selection field component such that only an outer part of the magnetic material 100 is magnetized, it is possible that saturation effects of the magnetized magnetic material 100 are already detectable with comparably low magnetic field strengths (amplitudes) of the magnetic selection field 211. For example, an iron rod of at least a few millimetres in diameter has a saturation magnetization in an external magnetic field of about 2 Tesla (field strength of the external field). Therefore, the non-linearity of the magnetization curve would be observed from around 1 Tesla (due to the de-magnetization factor of 0.5 perpendicular to the rod axis). So, only at these high field strengths, substantial harmonics generation can be expected. With the inventive arrangement having a time-varying selection field component of a frequency of at least 100 Hz—preferably a much higher frequency—it is possible to generate substantial harmonics already at 2.5 mT (the required frequency of the selection field would in that case be in the range of around 25 kHz). At such frequencies of the selection field 211, only the outer parts of the magnetic material 100 is saturated or influenced by the presence of the magnetic selection field 211. The magnetic drive field 221 needs to have a still higher frequency than the magnetic selection field 211. According to the present invention, the frequency of the magnetic drive field 221 is at least 5 times the frequency of the magnetic selection field 211, preferably around 10 times the frequency of the magnetic selection field 211. Therefore, the magnetic flux changes due to the magnetic drive field 221 enter the magnetic material 100 (due to still a smaller skin depth at the frequencies of the magnetic drive field 221) only at the periphery of the magnetic material 100. This is shown in an example in FIG. 3. The magnetic field variations that the receiving means 230 are supposed to be sensitive are preferably in a frequency range of approximately 50 kHz to several 100 MHz.

FIG. 3 shows an example of a magnetic material 100 of the kind used together with an arrangement 10 of the present invention. It comprises for example a steel rod having an inner material part 101. Towards the periphery of the steel rod 100 as an example of the magnetic material 100, there are two further zones 102, 103 of the material. The second zone 103 of these zones can be imagined as the zone of the magnetic material 100 where the magnetic drive field 221 interacts. The first zone 102 and the second zone 103 can be imagined as the zone of the magnetic material 100 where the magnetic selection field 211 interacts. The magnetic material 100 is preferably homogeneous also from the inner part towards the further zones 102, 103. By detecting and locating the magnetic material 100 in its second zone 103 by means of the magnetic drive field 221, it is possible to image the extension of the whole magnetic material 100 accessible to the inventive method (i.e. the whole second zone 103 of the magnetic material 100). For the case of iron rods, it is e.g. possible to determine the diameter of the iron rods.

The size of the first sub-zone 301 is dependent on the one hand on the strength of the gradient of the magnetic selection field 211 and on the other hand on the field strength of the magnetic field required for saturation. For a sufficient saturation of the magnetic material 100 at a magnetic field strength of 2.5 mT and a gradient (in a given space direction) of the field strength of the magnetic selection field 211 amounting to 250 mT/m, it will be possible to separate two objects having a distance of 10 mm. Due to distortion effects, an imaging of the magnetic material 100 having a sufficient spatial resolution is only possible by means of complex mathematical computations. If harmonics are already produced by a smaller (maximal) field strength of the magnetic selection field (especially at higher frequencies) of e.g. 100 μT, then only 10 mT/m could also be sufficient to separate two spaced objects of the magnetic material 100. The size (or diameter) of a magnetic material 100 can be determined depending on the signal strength of the acquired signals. This is sufficient, e.g. to determine the resultant (non-corroded) diameter of steel rods inside of buildings.

FIGS. 4a and 4b show the magnetization characteristic, that is, the variation of the magnetization M of a part of the magnetic material 100 (not shown in FIGS. 4a and 4b) as a function of the field strength H at the location of that part of the magnetic material 100. It appears that the magnetization M no longer changes beyond a field strength +H_{c} and below a field strength −H_{c}, which means that a saturated magnetization is involved. The magnetization M is not saturated between the values +H_{c} and −H_{c}.

FIG. 4a illustrates the effect of a sinusoidal magnetic field H(t) on a part of the magnetic material 100 where the absolute values of the resulting sinusoidal magnetic field H(t) (i.e. “seen by that part of the magnetic material 100”) are lower than the magnetic field strength required to statically saturate the magnetic material 100 completely, but where the absolute values of the resulting sinusoidal magnetic field H(t) (i.e. “seen by that part of the magnetic material 100”) is higher than the magnetic field strength required to dynamically saturate that part of the magnetic material 1 00. The magnetization of that part of the magnetic material 100 reciprocates between its saturation values at the rhythm of the frequency of the magnetic field H(t). The resultant variation in time of the magnetization is denoted by the reference M(t) on the right hand side of FIG. 4a. It appears that the magnetization also changes periodically and that the magnetization of such a part of the magnetic material 100 is periodically reversed.

The dashed part of the line at the centre of the curve denotes the approximate mean variation of the magnetization M(t) as a function of the field strength of the sinusoidal magnetic field H(t). As a deviation from this centre line, the magnetization extends slightly to the right when the magnetic field H increases from −H_{c} to +H_{c} and slightly to the left when the magnetic field H decreases from +H_{c} to −H_{c}. This known effect is called a hysteresis effect which underlies a mechanism for the generation of heat. The hysteresis surface area which is formed between the paths of the curve and whose shape and size are dependent on the material, is a measure for the generation of heat upon variation of the magnetization.

FIG. 4b shows the effect of a sinusoidal magnetic field H(t) on which a further magnetic field H₁ (having a frequency that is small relative to the frequency of the sinusoidal magnetic field H(t)) is superposed. Because the magnetization is in the saturated state, it is practically not influenced by the sinusoidal magnetic field H(t). The magnetization M(t) remains constant in time at this area. Consequently, the magnetic field H(t) does not cause a change of the state of the magnetization.

FIG. 5 shows a so-called single sided inventive arrangement 10 known from the International Patent Application WO 2004/091721 A1. Such an arrangement 10 comprises a first side 11 and furthermore a plurality of coils 4, 5 used to generate the magnetic selection field 211 (not shown in FIG. 5) and the magnetic drive field 221 (not shown in FIG. 5) and used to constitute the receiving means 230. Such an arrangement allows for an improved accessibility of the region of action 300.

1. An arrangement (10) for detecting and/or locating a magnetic material (100) in a region of action (300), which arrangement comprises:
selection means (210) for generating a magnetic selection field (211) having a pattern in space of its magnetic field strength such that a first sub-zone (301) having a low magnetic field strength and a second sub-zone (302) having a higher magnetic field strength are formed in the region of action (300),
drive means (220) for changing the position in space of the two sub-zones (301, 302) in the region of action (300) by means of a magnetic drive field (221) so that the magnetization of the magnetic material (100) changes locally,
receiving means (230) for acquiring detection signals, which detection signals depend on the magnetization in the region of action (300), which magnetization is influenced by the change in the position in space of the first and second sub-zone (301, 302),
wherein the magnetic selection field (211) comprises at least a time-variable field component varying at a frequency of at least about 100 Hz.

2. An arrangement (10) according to claim 1, wherein the time-variable field component of the magnetic selection field (211) is varying at a frequency of at least about 10 kHz, preferably of at least 25 kHz.

3. An arrangement (10) according to claim 1, wherein the frequency of the time-variable field component of the magnetic selection field (211) and the magnetic field strength of the magnetic selection field (211) is chosen such that the magnetic material (100) to be detected is at least partly saturated.

4. An arrangement (10) according to claim 1, wherein the magnetic drive field (221) is a time-variable field varying at a frequency of at least about 5 times to about 100 times the frequency of the time-variable field component of the magnetic selection field (211).

5. An arrangement (10) according to claim 1, wherein the magnetic selection field (211) furthermore comprises a time-constant field component in addition to the time-variable field component of the magnetic selection field (211).

6. An arrangement (10) according to claim 1, wherein the arrangement (10) is provided as a single-sided arrangement.

7. An arrangement (10) according to claim 1, wherein the selection means (210) and the drive means (220) and the receiving means (230) are provided as coils comprising a magnetically soft core material.

8. A method for detecting and/or locating a magnetic material (100) in a region of action (300), wherein the method comprises the steps of
generating a magnetic selection field (211) having a pattern in space of its magnetic field strength such that a first sub-zone (301) having a low magnetic field strength and a second sub-zone (302) having a higher magnetic field strength are formed in the region of action (300),
changing the position in space of the two sub-zones (301, 302) in the region of action (300) by means of a magnetic drive field (221) formed by drive signals so that the magnetization of the magnetic material (100) changes locally,
acquiring detection signals, which detection signals depend on the magnetization in the region of action (300), which magnetization is influenced by the change in the position in space of the first and second sub-zone (301, 302), wherein the magnetic selection field (211) comprises at least a time-variable field component varying at a frequency of at least about 100 Hz.

9. A method according to claim 8, wherein the time-variable field component of the magnetic selection field (211) is varying at a frequency of at least about 10 kHz or at a frequency of at least 25 kHz.

10. A method according to claim 8, wherein the frequency of the time-variable field component of the magnetic selection field (211) and the magnetic field strength of the magnetic selection field (211) is chosen such that the magnetic material (100) to be detected is at least partly saturated.

11. A method according to claim 8, wherein the magnetic drive field (221) is a time-variable field varying at a frequency of at least about 5 times to about 100 times the frequency of the time-variable field component of the magnetic selection field (211).

12. A method according to claim 8, wherein the magnetic material (100) comprises a ferromagnetic material and/or a ferrimagnetic material and/or an antiferromagnetic material and/or an antiferrimagnetic material.

13. A method according to claim 8, wherein the frequency of the time-variable field component of the magnetic selection field (211) is chosen such that the magnetic field strength of the magnetic selection field (211) in order to saturate at least partly an outer layer of the magnetic material (100) can be chosen inferior to 500 mT, preferably inferior to 50 mT, very preferably inferior to 5 mT.

14. A method according to claim 8, wherein the magnetic material (100) comprises iron rods inside of an insulation material.

15. Use of an arrangement according to claim 1 in the examination of soils and/or in the examination of human and/or animal bodies in the examination of buildings, the soils and/or bodies and/or buildings comprising metallic soft magnetic material as magnetic material (100), especially iron rods as magnetic material (100) inside of an insulation material.
